(19) United States
(12) Patent Application Publication
(10) Pub. No.: US 2025/0231240 A1
(43) Pub. Date: Jul. 17, 2025

(54) APPARATUS FOR DETECTING DISCONNECTION OF MOTOR

(71) Applicant: Hanon Systems, Daejeon (KR)

(72) Inventors: Jin Hyun JANG, Daejeon (KR); Sang Hun KIM, Daejeon (KR); Byoung Su LEE, Daejeon (KR)

(73) Assignee: Hanon Systems, Daejeon (KR)

(21) Appl. No.: 19/022,561

(22) Filed: Jan. 15, 2025

(30) Foreign Application Priority Data
Jan. 15, 2024 (KR) 10-2024-0005807

(51) Int. Cl. G01R 31/34; G01R 25/00

(52) U.S. Cl. CPC G01R 31/343; G01R 25/00

(57) ABSTRACT

A motor disconnection detection apparatus according to one embodiment may include a phase current detection part which detects a phase current at a specific alignment angle and a specific time within a motor alignment period and a motor disconnection detection part which detects disconnection of a motor based on the detected phase current.

### CROSS-REFERENCE TO RELATED APPLICATION

This application claims priority to and the benefit of Korean Patent Application No. 10-2024-0005807, filed on Jan. 15, 2024, the disclosure of which is incorporated herein by reference in its entirety.

### BACKGROUND

### 1. Field of the Invention

One embodiment of the present invention relates to an apparatus and method for detecting disconnection of a motor, and specifically, to a logic for detecting disconnection of a motor.

### 2. Discussion of Related Art

In the case of a vehicle such as an electronic vehicle, various motors are used. In the case of a specific motor, since the specific motor may relate to an accident of the vehicle, it needs attention.

However, since a logic for detecting disconnection of a motor is not realized, there are many problems.

Accordingly, a logic for detecting disconnection of a motor to solve such problems will be proposed.

### SUMMARY OF THE INVENTION

According to an embodiment of the present invention, there is provided a motor disconnection detection apparatus including a phase current detection part which detects a phase current at a specific alignment angle and a specific time within a motor alignment period and a motor disconnection detection part which detects disconnection of a motor based on the detected phase current.

The phase current detection part according to one embodiment may set an alignment angle of at least some of a U-phase, a V-phase, and a W-phase to 30°.

The motor disconnection detection part according to one embodiment may determine whether the disconnection of the motor occurs based on phase currents detected a plurality of times within the specific time.

The motor disconnection detection part according to one embodiment may determine that the disconnection of the motor occurs when each of the detected phase currents is less than 0.5 A.

The motor disconnection detection part according to one embodiment may determine whether the disconnection of the motor occurs based on 30 ms, 60 ms, and 90 ms periods within a time of 100 ms.

When the motor disconnection detection part determines that disconnection occurs in each of the U-phase, the V-phase, and the W-phase in all 30 ms, 60 ms, and 90 ms periods, the motor disconnection detection part according to one embodiment may determine that the disconnection of the motor occurs.

When the motor disconnection detection part determines that disconnection occurs at least one of the U-phase, the V-phase, and the W-phase, the motor disconnection detection according to one embodiment may determine that the disconnection of the motor occurs.

According to another embodiment of the present invention, there is provided a method of detecting disconnection of a motor, which includes detecting a phase current at a specific alignment angle and a specific time within a motor alignment period, and detecting disconnection of a motor based on the detected phase current. The detecting of the phase current according to one embodiment may include setting an alignment angle of at least some of a U-phase, a V-phase, and a W-phase to 30°.

The detecting of the disconnection of the motor according to one embodiment may include determining whether the disconnection of the motor occurs based on phase currents detected a plurality of times within the specific time.

The detecting of the disconnection of the motor according to one embodiment may include determining that the disconnection of the motor occurs when each of the detected phase currents is less than 0.5 A.

The detecting of the disconnection of the motor according to one embodiment may include determining whether disconnection of the motor occurs based on 30 ms, 60 ms, and 90 ms periods within a time of 100 ms.

The detecting of the disconnection of the motor according to one embodiment may include determining that the disconnection of the motor occurs when it is determined that disconnection occurs in each of the U-phase, the V-phase, and the W-phase in all 30 ms, 60 ms, and 90 ms periods.

The detecting of the disconnection of the motor according to one embodiment may include determining that the disconnection of the motor occurs when it is determined that disconnection occurs in at least one of the U-phase, the V-phase, and the W-phase.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a block diagram illustrating a motor disconnection detection apparatus according to one embodiment;

FIG. 2 is a flowchart illustrating a method of detecting disconnection of a motor according to one embodiment;

FIG. 3 is a view showing an alignment angle of the method of detecting disconnection of a motor according to one embodiment;

FIG. 4 is a view illustrating the method of detecting disconnection of a motor according to one embodiment; and

FIG. 5 is a flowchart illustrating the method of detecting disconnection of a motor according to one embodiment.

### DETAILED DESCRIPTION OF EXEMPLARY EMBODIMENTS

Hereinafter, exemplary embodiments of the present invention will be described in detail with reference to the accompanying drawings.

However, the technical spirit of the present invention is not limited to some embodiments which will be described and may be implemented in a variety of different forms, and one or more components of the embodiments may be selectively combined, substituted, and used within the range of the technical spirit of the present invention. In addition, unless clearly and specifically defined otherwise by the context, all terms (including technical and scientific terms) used herein can be interpreted as having meanings customarily understood by those skilled in the art, and the meanings of generally used terms, such as those defined in commonly used dictionaries, will be interpreted in consideration of contextual meanings of the related art.

In addition, the terms used in the embodiments of the present invention are considered in a descriptive sense only and not to limit the present invention.

In the present specification, unless specifically indicated otherwise by the context, singular forms include plural forms, and in a case in which “at least one (or one or more) among A, B, and C” is described, this may include at least one combination among all possible combinations of “A”, “B”, and “C”.

In addition, in descriptions of components of the present invention, terms such as “first,” “second,” “A,” “B,” “(a),” and “(b)” may be used.

The terms are only to distinguish one component from another component, and the essence, order, and the like of the components are not limited by the terms. In addition, it should be understood that, when a first component is referred to as being “connected,” “coupled,” or “linked” to a second component, such a description may include both a case in which the first component is directly connected, coupled, or linked to the second component, and a case in which the first component is connected or coupled to the second component with a third component disposed therebetween.

In addition, when a first component is described as being formed or disposed “on (above)” or “under (below)” a second component, such a description includes both a case in which the two components are formed or disposed in direct contact with each other and a case in which one or more other components are interposed between the two components. In addition, when the first component is described as being formed “on (above) or under (below)” the second component, such a description may include a case in which the first component is formed at an upper side or a lower side with respect to the second component.

Hereinafter, when embodiments are described in detail with reference to the accompanying drawings, components that are the same or correspond to each other will be denoted by the same or corresponding reference numerals in all drawings, and redundant descriptions will be omitted.

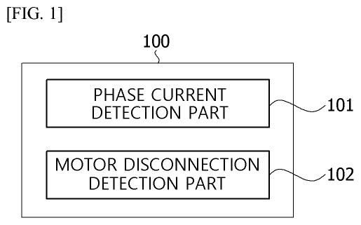

FIG. 1 is a block diagram illustrating a motor disconnection detection apparatus according to one embodiment.

According to one embodiment, a motor disconnection detection apparatus 100 may include a phase current detection part 101 which detects a phase current within a motor alignment period at a specific alignment angle and a specific time and a motor disconnection detection part 102 which detects disconnection of the motor based on the detected phase current.

According to one embodiment, the specific alignment angle may be 30°, and the specific time may be 30 ms for each of three times.

According to one embodiment, components of the motor disconnection detection apparatus may include at least some of a current meter, a vehicle component, a motor, machine, a circuit, a semiconductor, a computing device, a memory, a processor, a data transceiver, and the like, and at least some of the components may be mechanically/physically/communicatively/electrically connected to at least some of other components.

According to one embodiment, the motor disconnection detection apparatus may be applied to an electric water pump (eWP) motor applied for vehicle thermal management.

According to one embodiment, the phase current detection part 101 may set an alignment angle of at least some of a U-phase, a V-phase, and a W-phase to 30°.

According to one embodiment, the motor disconnection detection part 102 may determine whether disconnection of the motor occurs based on phase currents detected a plurality of times for a specific time. The motor may include a vehicle motor or eWP motor.

According to one embodiment, the motor disconnection detection part 102 may determine that disconnection of the motor occurs when all detected phase currents are smaller than 0.5 Amperes (A).

According to one embodiment, the motor disconnection detection part 102 may determine whether disconnection of the motor occurs based on 30 ms, 60 ms, and 90 ms periods within a time of 100 ms.

According to one embodiment, when the motor disconnection detection part 102 determines that disconnection occurs in each of the U-phase, the V-phase, and the W-phase in all 30 ms, 60 ms, and 90 ms periods, the motor disconnection detection part 102 may determine that the disconnection of the motor occurs.

According to one embodiment, when the motor disconnection detection part 102 determines that disconnection occurs in at least one of the U-phase, the V-phase, and the W-phase, the motor disconnection detection part 102 may determine that the disconnection of the motor occurs.

According to one embodiment, the motor disconnection detection apparatus has an effect of solving a problem that the motor is controlled using only one phase or two phases in which disconnection does not occur among three phases of the motor so that motor control performance is badly affected and the motor is damaged when a phenomenon of no detection of disconnection of the eWP motor occurs.

According to one embodiment, the motor disconnection detection apparatus has an advantage of determining motor disconnection when compared to a case in which there is no motor disconnection logic or to a logic of determining motor disconnection based on only whether the motor starts normally.

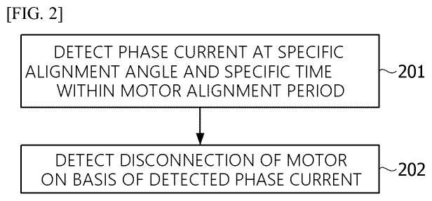

FIG. 2 is a flowchart illustrating a method of detecting disconnection of a motor according to one embodiment.

According to one embodiment, each operation of the method of detecting disconnection of a motor may be performed by at least some of the components of the motor disconnection detection apparatus.

In operation 201, the motor disconnection detection apparatus may detect a phase current at a specific alignment angle and a specific time within a motor alignment period.

In operation 202, the motor disconnection detection apparatus may detect disconnection of the motor based on the detected phase current.

According to one embodiment, the motor disconnection detection apparatus may set an alignment angle of at least some of a U-phase, a V-phase, and a W-phase to 30°.

According to one embodiment, the motor disconnection detection apparatus may determine whether disconnection of the motor occurs based on phase currents detected a plurality of times within a specific time.

According to one embodiment, the motor disconnection detection apparatus may determine that the disconnection of the motor occurs when all detected phase currents are less than 0.5 A.

According to one embodiment, the motor disconnection detection apparatus may determine whether disconnection of the motor occurs based on 30 ms, 60 ms, and 90 ms periods within a time of 100 ms.

According to one embodiment, when the motor disconnection detection apparatus determines that disconnection occurs in each of the U-phase, the V-phase, and the W-phase in all 30 ms, 60 ms, and 90 ms periods, the motor disconnection detection apparatus may determine that the disconnection of the motor occurs.

According to one embodiment, when the motor disconnection detection apparatus determines that disconnection occurs in at least one of the U-phase, the V-phase, and the W-phase, the motor disconnection detection apparatus may determine that disconnection of the motor occurs.

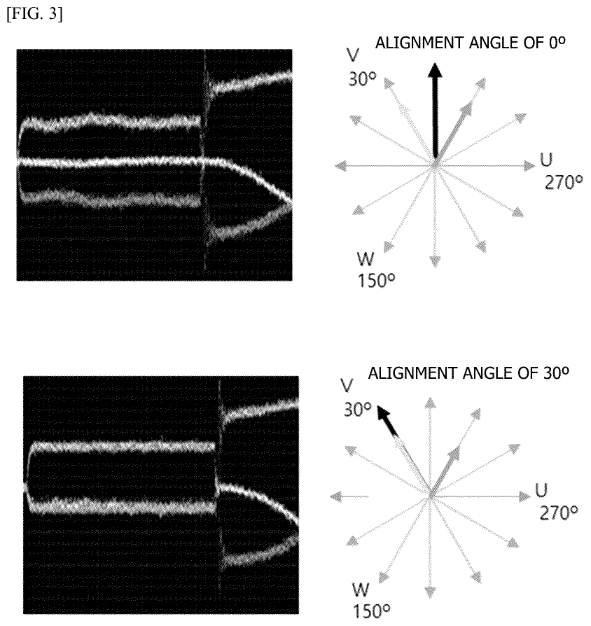

FIG. 3 is a view showing an alignment angle of the method of detecting disconnection of a motor according to one embodiment.

According to one embodiment, the motor disconnection detection apparatus may detect a phase current within a motor alignment period and provide an eWP motor disconnection detection logic.

A motor such as the eWP motor to which a sensorless algorithm is applied may be driven in the order of align→open loop→close loop when starting.

In order to align a start position of the open loop, a current may be applied for a predetermined time in an arbitrary alignment direction.

In this case, since an electrical angle is fixed, a phase current has a stepped wave instead of a sine wave.

According to one embodiment, since the amount of a phase current is converged to zero in an alignment period when the disconnection of the motor occurs, the motor disconnection detection apparatus may determine that disconnection occurs when the amount of the phase current is less than 0.5 A in the alignment period.

According to one embodiment, the motor disconnection detection apparatus may select/set a proper alignment angle to determine disconnection in all three phases of the motor because currents may be applied to all three phases or currents may be applied to only two phases according to the alignment angle in an alignment period. As illustrated at an upper side in FIG. 3, when an alignment angle (block arrow) is 0°, since a current is applied to only the V-phase (arrow) and the W-phase (arrow), and a current is not applied to the U-phase, only the currents of the V-phase and the W-phase may be measured, and thus disconnection of all three phases may not be determined. Accordingly, as illustrated at a lower side in FIG. 3, since the motor disconnection detection apparatus may apply a current to all the U-phase, the V-phase, and the W-phase when an alignment angle is set to 30°, disconnection may be determined in all three phases. (In the case of 30°, in the U-phase and the W-phase, -current is generated, however, when determination is performed, since absolute values are compared, disconnection determination is possible.)

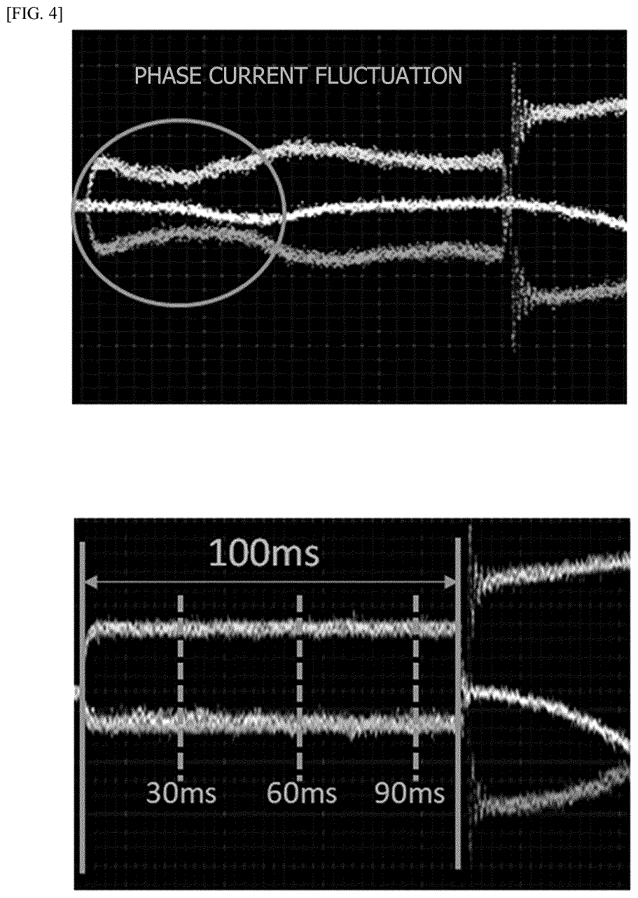

FIG. 4 is a view illustrating the method of detecting disconnection of a motor according to one embodiment.

According to one embodiment, the motor disconnection detection apparatus may determine motor disconnection in an alignment period when the motor starts.

Although the motor disconnection detection apparatus may apply a current using a current control of a close loop method, the motor disconnection detection apparatus may apply a current by applying a predetermined voltage in an open loop method when applying a current in an alignment period.

In the method of applying the predetermined voltage as illustrated at an upper side in FIG. 4, since a stepped wave in an alignment period fluctuates according to a temperature, an existing rotator position, or the like, it may be incorrectly determined that disconnection occurs even when disconnection does not occur. Accordingly, when the motor disconnection detection apparatus performs detection three times within divided periods of an alignment period and determines that disconnection occurs three times, the motor disconnection detection apparatus may determine that motor disconnection occurs. As illustrated at a lower side in FIG. 4, the motor disconnection detection apparatus may perform detection three times in 30 ms, 60 ms, and 90 ms periods within an alignment period of 100 ms.

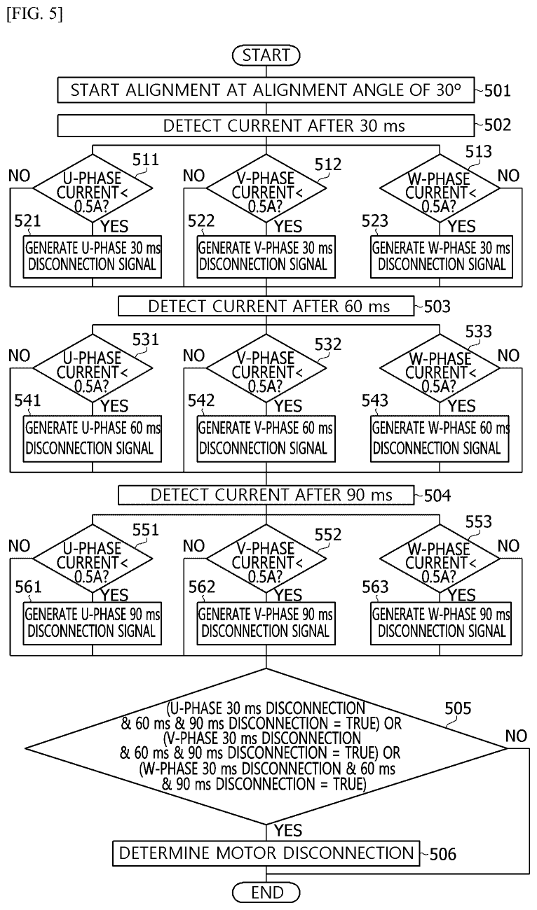

FIG. 5 is a flowchart illustrating the method of detecting disconnection of a motor according to one embodiment.

In operation 501, the motor disconnection detection apparatus may perform control such that motor alignment starts at an alignment angle of 30°.

In operation 502, the motor disconnection detection apparatus may detect a current after 30 ms within 100 ms.

In operation 511, the motor disconnection detection apparatus may check whether a U-phase current is less than 0.5 A.

In operation 512, the motor disconnection detection apparatus may check whether a V-phase current is less than 0.5 A.

In operation 513, the motor disconnection detection apparatus may check whether a W-phase current is less than 0.5 A.

In operation 521, when the U-phase current is less than 0.5 A, the motor disconnection detection apparatus may generate a U-phase 30 ms disconnection signal or determine that there is U-phase disconnection.

In operation 522, when the V-phase current is less than 0.5 A, the motor disconnection detection apparatus may generate a V-phase 30 ms disconnection signal or determine that there is V-phase disconnection.

In operation 523, when the W-phase current is less than 0.5 A, the motor disconnection detection apparatus may generate a W-phase 30 ms disconnection signal or determine that there is W-phase disconnection.

In operation 503, the motor disconnection detection apparatus may detect a current after 60 ms within 100 ms.

In operation 531, the motor disconnection detection apparatus may check whether a U-phase current is less than 0.5 A.

In operation 532, the motor disconnection detection apparatus may check whether a V-phase current is less than 0.5 A.

In operation 533, the motor disconnection detection apparatus may check whether a W-phase current is less than 0.5 A.

In operation 541, when the U-phase current is less than 0.5 A, the motor disconnection detection apparatus may generate a U-phase 60 ms disconnection signal or determine that there is U-phase disconnection.

In operation 542, when the V-phase current is less than 0.5 A, the motor disconnection detection apparatus may generate a V-phase 60 ms disconnection signal or determine that there is V-phase disconnection.

In operation 543, when the W-phase current is less than 0.5 A, the motor disconnection detection apparatus may generate a W-phase 60 ms disconnection signal or determine that there is W-phase disconnection.

In operation 504, the motor disconnection detection apparatus may detect a current after 90 ms within 100 ms.

In operation 551, the motor disconnection detection apparatus may check whether a U-phase current is less than 0.5 A.

In operation 552, the motor disconnection detection apparatus may check whether a V-phase current is less than 0.5 A.

In operation 553, the motor disconnection detection apparatus may check whether a W-phase current is less than 0.5 A.

In operation 561, when the U-phase current is 0.5 A, the motor disconnection detection apparatus may generate a U-phase 90 ms disconnection signal or determine that there is U-phase disconnection.

In operation 562, when the V-phase current is 0.5 A, the motor disconnection detection apparatus may generate a V-phase 90 ms disconnection signal or determine that there is V-phase disconnection.

In operation 563, when the W-phase current is 0.5 A, the motor disconnection detection apparatus may generate a W-phase 90 ms disconnection signal or determine that there is W-phase disconnection.

In operation 505, the motor disconnection detection apparatus may check whether the disconnection signals are generated or whether there is the U-phase disconnection in all the U-phase 30 ms, 60 ms, and 90 ms. In addition, the motor disconnection detection apparatus may check whether the disconnection signals are generated or whether there is the V-phase disconnection in all the V-phase 30 ms, 60 ms, and 90 ms. In addition, the motor disconnection detection apparatus may check whether the disconnection signals are generated or whether there is the W-phase disconnection in all the U-phase 30 ms, 60 ms, and 90 ms.

In operation 506, when the motor disconnection detection apparatus determines that the disconnection signals are generated or there is the U-phase disconnection in all the U-phase 30 ms, 60 ms, and 90 ms, the motor disconnection detection apparatus may ultimately determine/decide that disconnection of the motor occurs. In addition, when the motor disconnection detection apparatus determines that the disconnection signals are generated or there is the V-phase disconnection in all the V-phase 30 ms, 60 ms, and 90 ms, the motor disconnection detection apparatus may ultimately determine/decide that disconnection of the motor occurs. In addition, when the motor disconnection detection apparatus determines that the disconnection signals are generated or there is the W-phase disconnection in all the W-phase 30 ms, 60 ms, and 90 ms, the motor disconnection detection apparatus may ultimately determine/decide that disconnection of the motor occurs.

Terms such as “unit” used in the present embodiment refer to software or a hardware component such as a field-programmable gate array (FPGA) or an application-specific integrated circuit (ASIC), and objects termed “unit” perform certain roles. However, the term “unit” is not limited to software or hardware. A “unit” may reside on an addressable storage medium or to operate one or more processors. Thus, in an example, the term “unit” includes components such as software components, object-oriented software components, class components, task components, processes, functions, properties, procedures, subroutines, segments of program code, drivers, firmware, micro-code, circuits, data, data bases, data structures, tables, arrays, and variables. Functions provided by these components and “units” may be combined into a smaller number of components and “units” or may be subdivided into additional components and “units.” Furthermore, the components and “units” may also be implemented to operate one or more central processing units (CPUs) within a device or a security multimedia card.

While the present invention has been described above with reference to exemplary embodiments, it may be understood by those skilled in the art that various modifications and changes of the present invention may be made within a range not departing from the spirit and scope of the present invention defined by the appended claims.

What is claimed is:

1. A motor disconnection detection apparatus comprising:
a phase current detection part which detects a phase current at a specific alignment angle and a specific time within a motor alignment period; and
a motor disconnection detection part which detects disconnection of a motor based on the detected phase current,
wherein the motor disconnection detection part determines whether the disconnection of the motor occurs based on phase currents detected a plurality of times within the specific time.

2. The motor disconnection detection apparatus of claim 1, wherein the phase current detection part sets an alignment angle of at least some of a U-phase, a V-phase, and a W-phase to 30°.

3. The motor disconnection detection apparatus of claim 1, wherein the motor disconnection detection part determines that the disconnection of the motor occurs when each of the detected phase currents is less than 0.5 A.

4. The motor disconnection detection apparatus of claim 1, wherein the motor disconnection detection part determines whether the disconnection of the motor occurs based on 30 ms, 60 ms, and 90 ms periods within a time of 100 ms.

5. The motor disconnection detection apparatus of claim 4, wherein, when the motor disconnection detection part determines that disconnection occurs in each of the U-phase, the V-phase, and the W-phase in all 30 ms, 60 ms, and 90 ms periods, the motor disconnection detection part determines that the disconnection of the motor occurs.

6. The motor disconnection detection apparatus of claim 2, wherein, when the motor disconnection detection part determines that disconnection occurs in at least one of the U-phase, the V-phase, and the W-phase, the motor disconnection detection determines that the disconnection of the motor occurs.

7. The motor disconnection detection apparatus of claim 1, which applies a current by applying a predetermined voltage in an open loop method.

8. The motor disconnection detection apparatus of claim 1, wherein:
the phase current detection part detects disconnection a plurality of times in at least some divided periods which are divided from the motor alignment period; and
when the motor disconnection detection part determines that the disconnection occurs all of the plurality of times, the motor disconnection detection part determines that the disconnection of the motor occurs.

9. A method of detecting disconnection of a motor, comprising:
detecting a phase current at a specific alignment angle and a specific time within a motor alignment period; and
detecting disconnection of a motor based on the detected phase current,
wherein the detecting of the disconnection of the motor includes determining whether the disconnection of the motor occurs based on phase currents detected a plurality of times within the specific time.

10. The method of claim 9, wherein the detecting of the phase current includes setting an alignment angle of at least some of a U-phase, a V-phase, and a W-phase to 30°.

11. The method of claim 9, wherein the detecting of the disconnection of the motor includes determining that the disconnection of the motor occurs when each of the detected phase currents is less than 0.5 A.

12. The method of claim 9, wherein the detecting of the disconnection of the motor includes determining whether the disconnection of the motor occurs based on 30 ms, 60 ms, and 90 ms periods within a time of 100 ms.

13. The method of claim 12, wherein the detecting of the disconnection of the motor includes determining that the disconnection of the motor occurs when it is determined that disconnection occurs in each of the U-phase, the V-phase, and the W-phase in all 30 ms, 60 ms, and 90 ms periods.

14. The method of claim 10, wherein the detecting of the disconnection of the motor includes determining that the disconnection of the motor occurs when it is determined that disconnection occurs in at least one of the U-phase, the V-phase, and the W-phase.

15. The method of claim 9, further comprising applying a current by applying a predetermined voltage in an open loop method.

16. The method of claim 9, wherein:
the detecting of the phase current includes detecting disconnection a plurality of times in at least some divided periods which are divided from the motor alignment period; and
the detecting of the disconnection of the motor includes determining that the motor disconnection occurs when it is determined that disconnection occurs all of the plurality of times.
